(19) United States
(12) Patent Application Publication
(10) Pub. No.: US 2023/0333190 A1
(43) Pub. Date: Oct. 19, 2023

(54) METHOD FOR ESTIMATING A MAGNETIC FIELD DEVIATION, A MAGNETIC RESONANCE DEVICE AND A COMPUTER PROGRAM PRODUCT

(71) Applicant: Siemens Healthcare GmbH, Erlangen (DE)

(72) Inventor: Stefan Popescu, Erlangen (DE)

(21) Appl. No.: 18/133,379

(22) Filed: Apr. 11, 2023

(30) Foreign Application Priority Data
Apr. 14, 2022 (EP) 22168603.3

(51) Int. Cl. G01R 33/565; G01R 33/387

(52) U.S. Cl. CPC G01R 33/56581; G01R 33/387

(57) ABSTRACT

A method for estimating a magnetic field deviation, a magnetic resonance device, and a computer program product are disclosed. In accordance with the method, at least one gradient value is provided, wherein each gradient value describes a gradient strength of the respective gradient magnetic field, e.g., the setpoint gradient magnetic field. The magnetic resonance device generates a main magnetic field in a main magnetic field direction. The at least one value of a deviation is estimated by applying the at least one gradient value to a magnetic field model. In this case, in accordance with a magnetic field model, a deviation of the gradient magnetic field from a setpoint gradient magnetic field is described by at least one vectorial component in a spatial direction deviating from the main magnetic field direction.

The present patent document claims the benefit of European Patent Application No. 22168603.3, filed Apr. 14, 2022, which is hereby incorporated by reference in its entirety.

### TECHNICAL FIELD

The disclosure relates to a method for estimating a magnetic field deviation, a magnetic resonance device, and a computer program product.

### BACKGROUND

In medical engineering, imaging using magnetic resonance (MR), also called magnetic resonance tomography (MRT) or magnetic resonance imaging (MRI), is characterized by high soft tissue contrasts. In this case, a human or animal patient may be positioned in an imaging volume of a magnetic resonance device. During a magnetic resonance scan radio-frequency excitation pulses, e.g., electromagnetic alternating fields, are irradiated into the patient, e.g., with the help of a radio-frequency antenna unit of the magnetic resonance device in accordance with a magnetic resonance sequence. This should be distinguished from a magnetic field generated by a magnetic coil unit of the magnetic resonance device, which may include a static main magnetic field and one or more overlapping gradient magnetic fields. The main magnetic field is generated by a main magnet, for example, a superconducting main magnet. Further, the gradient magnetic fields are generated with the help of a gradient coil unit of the magnetic resonance device and may be used for the position encoding of the magnetic resonance signals. The gradient coil unit may include multiple gradient coils, wherein each of the multiple gradient coils is designed to generate a (partial) gradient magnetic field with a magnetic field gradient in a particular spatial direction, e.g., X, Y, or Z. (The term “spatial direction” is used below synonymously with the term “direction”.)

The excitation pulses cause nuclear spins to be excited in the patient, which precess around the field direction of the main magnetic field, and magnetic resonance signals to be triggered. (The main magnetic field direction may be defined as the Z direction. The Z axis of the magnetic resonance device is oriented in the Z direction. Z direction and Z axis are used synonymously below.) The magnetic resonance signals are received by the magnetic resonance device and used for the reconstruction of magnetic resonance images.

Throughout this disclosure, symbols printed in bold are used to designate vector variables (for example, B is the vector value of the magnetic field) and normal symbols are used to designate the amount of these vectors, i.e., B=|B|.

Since its inception, the MR imaging method has been based on ideal assumptions as regards the magnetic fields used to acquire the magnetic resonance images, in other words the static main magnetic field B₀ and the dynamic, in particular temporally and spatially variable, signal-encoding gradient magnetic fields, which are controlled by the sequence parameters GX, GY, and GZ. In this case, the sequence parameters GX, GY, and GZ are gradient values, which in each case describe a gradient strength, in particular a temporally and spatially variable gradient strength, of a respective gradient magnetic field.

During a performance of a magnetic resonance sequence, gradient pulses and/or gradient waveforms GX(t), GY(t), and GZ(t) may be generated using the gradient coil unit. In this case, the gradient strength of a gradient magnetic field varies as a function of time t. It is assumed that the strength of the static main magnetic field within the imaging volume has a uniform distribution for an accuracy of less than a few parts per million (ppm). It is also assumed that the magnetic field lines are perfectly straight and parallel, i.e., the main magnetic field B₀ is oriented along the main magnetic field direction, referred to below as the Z direction, where B₀=BZ₀, and that there are no transverse vector components, i.e., BX0=BY₀=0. Furthermore, it is also assumed for the gradient magnetic fields that they are oriented exclusively along the Z direction, wherein they modulate the strength of BZ₀ linearly as a function of the spatial coordinate (x,y,z), i.e.:

BZ(x,y,z)=BZ₀+GX·x+GY·y+GZ·z,

and BX(x,y,z)=BY(x,y,z)=0

Unfortunately, the actual relationships in magnetic resonance devices may deviate appreciably from these idealized assumptions. The static main magnetic field B₀ may be significantly non-linear, in particular at the periphery of the imaging volume (also called the field of view, FOV). Associated with these non-linearities are spatial variations in the field strength B₀(x,y,z) as well as smaller local deviations in the field direction, i.e., in the magnetic vector field B₀(x,y,z), deviating from the main magnetic field direction, in other words the Z direction. These disadvantages may occur in the case of designs of magnetic resonance devices that aim to reduce costs for the magnetic unit. It is well known that a highly homogeneous main magnet with an increasingly large bore opening results in an appreciable rise in production costs.

In addition, it has long been known that a real gradient coil does not generate ideal gradient magnetic fields that are only oriented along the Z axis and perfectly parallel to the direction of B₀. Instead, both the axial gradient coil (ZGC) and the transverse gradient coils (XGC and YGC) generate a quadrupolar field distribution with concomitant field components that are orthogonal to the Z axis. These components are known in the specialist literature as concomitant or Maxwell terms and they are unavoidably a series of physical laws (as described by the Maxwell equations); accordingly, the vector field of the magnetic field has an insignificant divergence, and a negligible rotation within the imaging volume.

The field errors described above generate specific image artifacts and hence require different recognition and correction measures. For example, the concomitant terms alter the local frequency of the magnetic resonance signal, leading to phase errors and geometric distortions in magnetic resonance images. Uncorrected or incompletely corrected errors in particular represent a major obstacle for quantitative magnetic resonance examinations.

The correction for the Maxwell terms in accordance with the prior art follows the method developed by Bernstein in the 1990s. This method is based on a development of the magnetic vector field B into a Taylor series, wherein certain assumptions and approximations A1 to A5 are made as follows:

A1: The gradient magnetic fields are perfectly linear in the imaging volume.

A2: There are no orthogonal X-Y gradient fields, i.e.,

$$\frac{\partial {B}_{y}}{\partial x} = \frac{\partial {B}_{x}}{\partial y} = 0$$

A3: The gradient magnetic fields have a cylindrical symmetry, i.e.,

$$\frac{\partial {B}_{x}}{\partial x} = \frac{\partial {B}_{y}}{\partial y}$$

A4: The main magnetic field B₀ is perfectly homogeneous and is oriented precisely along the Z axis.

A5: The terms of the Taylor series development that are weighted with (1/B₀)² and (1/B₀)³ may be disregarded.

Since its introduction, the Bernstein method has been used to take account of Maxwell terms in various MR applications, as is further disclosed in detail, for example, in U.S. Pat. Nos. 5,877,629A, 5,923,168A, and 6,011,392A. A publication by Wang et al., “FMRI based on transition-band balanced SSFP in comparison with EPI on a high-performance 0.55 T scanner”, Magn Reson Med. 2021;85:3196-3210, which appeared recently shows that the Bernstein method with its assumptions is still being applied without change.

Above all however, assumption A4 of the Bernstein method is not satisfied by more recent models of magnetic resonance devices, in which the size of the patient bore is expanded to 80 cm and at the same time the diameter of the FOV is increased to more than 55 cm. In addition, in the case of low-field magnetic resonance devices, which in particular work in the range between 0.2 and 0.5 T or even less, and in the case of relatively strong gradients the approximation A5 results in considerable errors.

### SUMMARY AND DESCRIPTION

An object of the present disclosure may be regarded as specifying an improved method for estimating a value of a deviation of a magnetic field, in particular of Maxwell terms, which in particular at least in part avoids unrealistic assumptions of the Bernstein method.

The scope of the present disclosure is defined solely by the appended claims and is not affected to any degree by the statements within this summary. The present embodiments may obviate one or more of the drawbacks or limitations in the related art.

Accordingly, a computer-implemented method is proposed for estimating, in particular determining and/or ascertaining, at least one value of a deviation, in particular of a Maxwell term. In this case, each value of a deviation, (in other words each of the at least one values of a deviation), describes a deviation of an actual gradient magnetic field from a setpoint gradient magnetic field, in particular a setpoint gradient magnetic field, of a magnetic resonance device. In this case, at least one gradient value is provided, wherein each gradient value describes a gradient strength of a respective setpoint gradient magnetic field. The magnetic resonance device generates a main magnetic field, in particular a static main magnetic field, in a main magnetic field direction, in particular in a spatial direction of the main magnetic field. The at least one actual gradient magnetic field and/or the at least one setpoint gradient magnetic field may overlap, in particular spatially, with the main magnetic field. The at least one value of a deviation is estimated by applying the at least one gradient value to a magnetic field model. In this case, in accordance with the magnetic field model, in particular using the at least one value of a deviation, the deviation of the actual gradient magnetic field from the respective setpoint gradient magnetic field by at least one vectoral component, in particular of a deviation field of the actual gradient magnetic field, in a spatial direction deviating from the main magnetic field direction is described.

The proposed method, in particular the estimation of the at least one value of a deviation, may be performed with the help of a computing unit. The computing unit may include one or more processors and/or one or more memory modules.

The at least one value of a deviation may be at least one Maxwell term and/or may be expressed by at least one Maxwell term. The at least one value of a deviation may include multiple values of a deviation, in particular multiple Maxwell terms. In particular, each of the multiple values of a deviation may describe part of the deviation of the actual gradient magnetic field from the setpoint gradient magnetic field. For example, a first value of a deviation of the multiple values of a deviation may describe a deviation in a first spatial direction and a second value of a deviation of the multiple values of a deviation may describe a deviation in a further spatial direction, in particular in a spatial direction orthogonal to the first spatial direction.

The actual gradient magnetic field may be a gradient magnetic field estimated in accordance with the magnetic field model. The actual gradient magnetic field may have a greater similarity to a gradient magnetic field actually existing in the magnetic resonance device than the setpoint gradient field. The actual gradient magnetic field may be identical to a gradient magnetic field actually existing in the magnetic resonance device. The setpoint gradient field may be an ideal gradient field, which in particular satisfies the above-described assumptions A1, A2, and/or A3 of the Bernstein method.

The gradient strength may be a measure of a change in a magnetic field, in particular of an amount of the magnetic field, dependent on a location and/or as a function of a location. The gradient strength may be a measure of a magnetic field gradient. The physical unit of the gradient strength may be specified in mT/m. The at least one gradient value may include multiple gradient values. Each of the multiple gradient values may describe a gradient strength of a respective setpoint gradient magnetic field. Each gradient value of the multiple gradient values may also describe an actual gradient strength of the respective actual gradient magnetic field. Each of these setpoint gradient magnetic fields or actual gradient fields may represent a respective gradient magnetic field in a respective spatial direction. These different gradient magnetic fields may overlap to form a total and/or resultant gradient magnetic field.

The setpoint gradient magnetic field and/or the associated gradient strength may be established by a magnetic resonance sequence, in particular by a gradient pulse of the magnetic resonance sequence. The gradient strength may be a sequence parameter of the magnetic resonance sequence.

For example, the at least one actual gradient magnetic field includes a first gradient magnetic field with a magnetic field gradient in a first spatial direction (e.g., the X direction), a second actual gradient magnetic field with a magnetic field gradient in a second spatial direction (e.g., the Y direction), and/or a third actual gradient magnetic field with a magnetic field gradient in a third spatial direction (e.g., the Z direction), wherein the first, second, and third spatial direction are orthogonal to one another. In particular, the first actual gradient magnetic field, the second actual gradient magnetic field, and/or the third actual gradient magnetic field overlap.

The magnetic resonance device may include a gradient coil unit. The gradient coil unit may include one or more gradient coils. Each of the actual gradient magnetic fields may be generated by a gradient coil, respectively provided therefor, of the gradient coil unit. For example, the gradient coil unit may include three gradient coils, wherein each of the three gradient coils respectively generates a gradient magnetic field, in particular an actual gradient magnetic field, in a respective spatial direction. For example, the gradient coil unit includes a gradient coil for generation of a gradient magnetic field, in particular an actual gradient magnetic field, with a magnetic field gradient in an X direction (X gradient coil, XGC), a gradient coil for generation of a gradient magnetic field, in particular an actual gradient magnetic field, with a magnetic field gradient in a Y direction (Y gradient coil, YGC) and a gradient coil for generation of a gradient magnetic field, in particular an actual gradient magnetic field, with a magnetic field gradient in a Z direction (Z gradient coil, ZGC).

The gradient coil unit, in particular at least one gradient coil thereof, may be operated dynamically. The gradient magnetic fields, in particular the actual gradient magnetic fields, may change over time. To this end, gradient pulses may be applied, which may cause a flow of electrical current in the at least one gradient coil. In accordance with the flow of electrical current and/or the geometry of the at least one gradient coil, it is possible to generate a gradient magnetic field, in particular an actual gradient magnetic field, which varies temporally and/or spatially. The gradient magnetic field of a respective gradient coil may have a gradient strength of up to 500 mT/m, up to 200 mT/m, up to 100 mT/m, or up to 50 mT/m. However, it cannot be ruled out that future magnetic resonance devices may have even higher maximum gradient strengths.

The magnetic resonance device may include a main magnet for generation of the main magnetic field. The main magnet may include a superconducting magnet. The main magnetic field may have a strength of 1.5 T, 3 T, or 7 T. The strength of the main magnetic field may be appreciably greater than the maximum strength of the at least one actual gradient magnetic field. The main magnetic field may be temporally constant. In an imaging volume of the magnetic resonance device, the main magnetic field is as homogeneous as possible, e.g., spatially constant. The main magnetic field may have a homogeneity in the imaging volume of less than 20 ppm, in particular less than 10 ppm.

The main magnet may have a cylinder geometry. The cylinder axis of the cylinder is mostly oriented in the main magnetic field direction. The cylinder axis of the cylinder may be the Z axis of the magnetic resonance device. The main magnetic field direction may be a spatial direction. The main magnetic field direction may be defined as a Z direction. The spatial direction deviating from the main magnetic field direction may be an X direction and/or a Y direction.

The estimation of the at least one value of a deviation may include determining and/or ascertaining the at least one value of a deviation. Using the at least one estimation value, magnetic resonance signals may be acquired and/or reconstructed.

During the acquisition of the magnetic resonance signals, a magnetic resonance sequence may be employed. The magnetic resonance sequence is advantageously adjusted using the estimated at least one value of a deviation.

A reconstruction of the magnetic resonance signals may include generation of at least one magnetic resonance image. In this case, the deviations of the actual gradient magnetic field from the setpoint gradient magnetic field are advantageously taken into account. The reconstructed magnetic resonance images thereby advantageously have a higher quality, in particular fewer artifacts.

Using the at least one deviation term ascertained, a correction of magnetic resonance signals, in particular of an encoding of magnetic resonance signals, may be performed. In particular, the correction includes calculation of a Larmor frequency dependent on the at least one value of a deviation.

A reconstruction of at least one magnetic resonance image may be performed, wherein, during the reconstruction of the at least one magnetic resonance image, phase errors caused by the deviation of the at least one actual gradient magnetic field are corrected using the at least one value of a deviation.

Thanks to the (new) magnetic field model, which describes the deviation of the actual gradient magnetic field from the setpoint gradient magnetic field by at least one vectorial component in a spatial direction deviating from the main magnetic field direction, the actual gradient magnetic field may advantageously be estimated more accurately. As a result, the acquisition and/or reconstruction may also take place more accurately.

The at least one vectorial component may have a linear dependency on at least one coordinate of a spatial direction. In particular, each of the at least one coordinates is assigned a (separate) spatial direction. For example, the X direction is assigned an x coordinate, the Y direction is assigned ay coordinate, and/or the Z direction is assigned a z coordinate. The at least one vectorial component may have a linear dependency on at least one coordinate of one of the following spatial directions: the main magnetic field direction and/or at least one spatial direction deviating from the main magnetic field direction. In particular, the spatial directions deviating from the main magnetic field direction are orthogonal to the main magnetic field direction and/or orthogonal to one another. In particular, the at least one vectorial component may in one spatial direction have a linear dependency on at least one coordinate of another spatial direction, in particular one orthogonal thereto.

The at least one vectorial component may have no higher-order dependency on a coordinate of a spatial direction. In particular, the at least one vectorial component in one spatial direction has no higher-order dependency on a coordinate of another spatial direction, in particular a spatial direction orthogonal thereto. A higher-order dependency may here in particular be regarded as a second-order dependency (quadratic dependency) and/or higher.

The at least one value of a deviation, in particular of the at least one Maxwell term, is advantageously represented by linear components. A Taylor series development in accordance with the Bernstein method which also contains higher-order terms may advantageously be dispensed with.

The magnetic field model disclosed herein is based in particular on the finding that the main magnetic field and/or the at least one actual gradient magnetic field may each be described by a vector field, wherein in accordance with the magnetic field model the rotation of the vector field of the main magnetic field and the rotation of each vector field of the at least one actual gradient magnetic field are zero in each case, and wherein in accordance with the magnetic field model the divergence of the vector field of the main magnetic field and the rotation of each vector field of the at least one actual gradient magnetic field are zero in each case.

The amounts of the vectors of the vector field of the magnetic field may describe a scalar field; the associated magnetic field gradient may be regarded as a vector which points in the direction of the steepest rise in these amounts, and the amount of the magnetic field gradient, e.g., the gradient strength, corresponds to the strength of this rise.

For example, the amounts of the first actual gradient magnetic field or associated setpoint gradient magnetic field change in the first direction, in particular linearly, and the amounts of the second gradient magnetic field or associated setpoint gradient magnetic field change in the second direction, in particular linearly, and the amounts of the third gradient magnetic field or associated setpoint gradient magnetic field change in the third direction, in particular linearly.

A vector field of the main magnetic field may be oriented in the main magnetic field direction, wherein the (actual) vector field of the at least one actual gradient magnetic field contains at least one vector which contains at least one vector component that deviates from the main magnetic field direction, wherein the at least one value of a deviation describes this deviation.

In particular, the (respective) vector field of the at least one actual gradient magnetic field contains vectors may contain a rectification in accordance with the associated setpoint gradient magnetic field, wherein the at least one deviation term describes an (actual) deviation from this (ideal) rectification. In particular, the rectification is the main magnet direction.

The first spatial direction may be an X direction, the second spatial direction may be a Y direction, and the third spatial direction may be a Z direction, wherein the Z direction is the main magnetic field direction, wherein in accordance with the magnetic field model the following applies for the at least one value of a deviation: B_{gx,x}=z·GX, B_{gx,y}=0 for the first actual gradient magnetic field, B_{gy,x}=0, B_{gy,y}=z·GY for the second actual gradient magnetic field and/or

$${B}_{gz , x} = - x \frac{G Z}{2} , {B}_{gz , y} = - y \frac{G Z}{2}$$

for the third actual gradient magnetic field. In this case, GX is the gradient strength in the X direction, GY the gradient strength in the Y direction, GZ the gradient strength in the Z direction, x is a coordinate in the X direction, y a coordinate in the Y direction, and z a coordinate in the Z direction.

In particular, B_{gx,x} describes a deviation (of the actual vector field of the gradient magnetic field) in the X direction, if a magnetic field gradient is created in the X direction. In particular, B_{gx,y} describes a deviation (of the actual vector field of the gradient magnetic field) in the Y direction, if a magnetic field gradient is created in the X direction. In particular, B_{gy,x} describes a deviation (of the actual vector field of the gradient magnetic field) in the X direction, if a magnetic field gradient is created in the Y direction. In particular, B_{gy,y} describes a deviation (of the actual vector field of the gradient magnetic field) in the Y direction, if a magnetic field gradient is created in the Y direction. In particular, B_{gz,x} describes a deviation (of the actual vector field of the gradient magnetic field) in the X direction, if a magnetic field gradient is created in the Z direction. In particular, B_{gz,y} describes a deviation (of the actual vector field of the gradient magnetic field) in the Y direction, if a magnetic field gradient is created in the Z direction.

In particular, the method may further include a provision of at least one parameter which describes the main magnetic field. Using the at least one parameter (describing the main magnetic field), the at least one gradient value and the (estimated) at least one value of a deviation it is possible to estimate, in particular calculate, an (actual) total magnetic field. The total magnetic field advantageously includes the main magnetic field and the at least one actual gradient magnetic field. In particular, to calculate the total magnetic field the vector fields of the main magnetic field and of the at least one actual gradient magnetic field are vectorially added.

In particular, the total magnetic field B(x,y,z) may be described by:

$$B ( x , y , z ) = [ ijk ] \cdot [ \begin{matrix}{B}_{0 x} ( x , y , z ) + z \cdot GX - x \frac{G Z}{2} \\ {B}_{0 y} ( x , y , z ) + z \cdot GY - y \frac{G Z}{2} \\ {B}_{0 z} ( x , y , z ) + x \cdot GX + y \cdot GY + z \cdot GZ\end{matrix} ]$$

In this case i, j, and k are unit vectors in the X direction, Y direction, and Z direction. B₀ₓ(x,y,z) is the location-dependent amount and/or the strength of the main magnetic field B₀(x,y,z) in the X direction, B_{0y}(x,y,z) is the location-dependent amount and/or the strength of the main magnetic field B₀(x,y,z) in the Y direction and B_{0z}(x,y,z) is the location-dependent amount and/or the strength of the main magnetic field B₀(x,y,z) in the Z direction.

A magnetic resonance scan may be performed, in particular by the magnetic resonance device, wherein prior to the magnetic resonance scan the at least one parameter of the main magnetic field has been calibrated, wherein during the magnetic resonance scan the calibrated at least one parameter is recalibrated, in particular in real time, wherein the estimation of the total magnetic field takes place using the calibrated at least one parameter. Advantageously thanks to the recalibration any drift artifacts in magnetic resonance images captured during the magnetic resonance scan may be reduced.

The calibration of the at least one parameter of the main magnetic field may take place with the help of a 3D magnetic field camera. The recalibration of the at least one parameter of the main magnetic field may take place with the help of at least one sensor, in particular a temperature sensor and/or a vibration sensor.

Further, a system control unit is proposed, which is configured to execute an above-described method for estimating at least one value of a deviation. The system control unit may include a computing unit with one or more processors and/or one or more memory modules.

Further, a magnetic resonance device with a system control unit is proposed, which is configured to execute an above- described method for estimating at least one value of a deviation.

The advantages of the proposed system control unit and/or of the magnetic resonance device substantially correspond to the advantages of the method for estimating at least one value of a deviation, which are set out above in detail. Features, advantages, or alternative forms of embodiment mentioned here may likewise also be transferred to the other claimed subject matters and vice versa.

Further, a computer program product is proposed, which includes a program and which may be loaded directly into a memory of a programmable system control unit of a magnetic resonance device and contains program means, e.g., libraries and auxiliary functions, in order to execute a method, if the computer program product is executed in the system control unit of the magnetic resonance device. The computer program product may include software with a source code which still has to be compiled and linked or which only has to be interpreted, or executable software code which for execution only has to be loaded into the system control unit. Thanks to the computer program product the method may be executed quickly, identically reproducibly, and robustly.

The computer program product is configured so that, by the system control unit, the computer program may execute the method acts. The system control unit meets the prerequisites, (e.g., an appropriate main memory, an appropriate graphics card, or an appropriate logic unit), so that the respective method acts may be executed efficiently. The computer program product may be stored on a computer-readable medium or on a network or server, from where the computer program product may be loaded into the processor of a local system control unit, wherein the processor may be connected to the magnetic resonance device directly or designed as part of the magnetic resonance device.

Furthermore, control information of the computer program product may be stored on an electronically readable data storage medium. The control information of the electronically readable data storage medium may be configured such that when the data storage medium is used in a system control unit of a magnetic resonance device it performs a method. Examples of electronically readable data storage media are a DVD, a magnetic tape or a USB stick, on which electronically readable control information, in particular software, is stored. If this control information is read from the data storage medium and is stored in a system control unit of the magnetic resonance device, all forms of embodiment of the previously described methods may be executed. Thus, the disclosure may also take as its starting point the computer-readable medium and/or the electronically readable data storage medium.

Further advantages, features, and details of the disclosure emerge from the exemplary embodiments described below and on the basis of the drawings. Parts corresponding to one another are provided with the same reference characters in all figures.

### BRIEF DESCRIPTION OF THE DRAWINGS

FIG. 1 shows an example of a magnetic resonance device in a schematic representation,

FIG. 2 shows an example of subunits of a gradient coil unit of a magnetic resonance device,

FIG. 3 shows am example of a flow diagram of a method for estimating at least one value of a deviation,

FIG. 4-10 show examples of the influence of magnetic vector fields representing Maxwell terms,

FIG. 11 shows an example of an addition of different magnetic field sources, in particular contributions to the total magnetic field.

### DETAILED DESCRIPTION

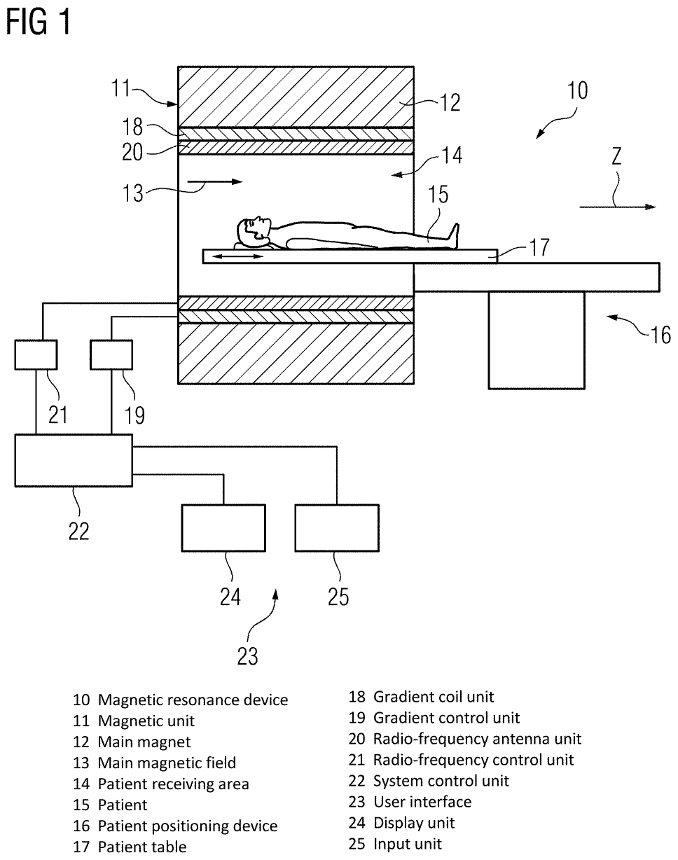

FIG. 1 schematically shows a magnetic resonance device 10. The magnetic resonance device 10 includes a magnetic unit 11, which has a main magnet 12 for generation of a strong and in particular temporally constant main magnetic field B₀. Furthermore, the magnetic resonance device 10 includes a patient receiving area 14 for receiving a patient 15. The patient receiving area 14 in the present exemplary embodiment is cylindrical in design and in a circumferential direction is cylindrically surrounded by the magnetic unit 11. Running in parallel to the direction of the main magnetic field B₀, the main magnetic field direction 13, is the cylinder axis of the patient receiving area 14, the Z axis in the spatial direction Z. The patient 15 may be pushed into the patient receiving area 14 by a patient positioning device 16 of the magnetic resonance device 10. To this end the patient positioning device 16 has a patient table 17 designed so as to be movable within the patient receiving area 14.

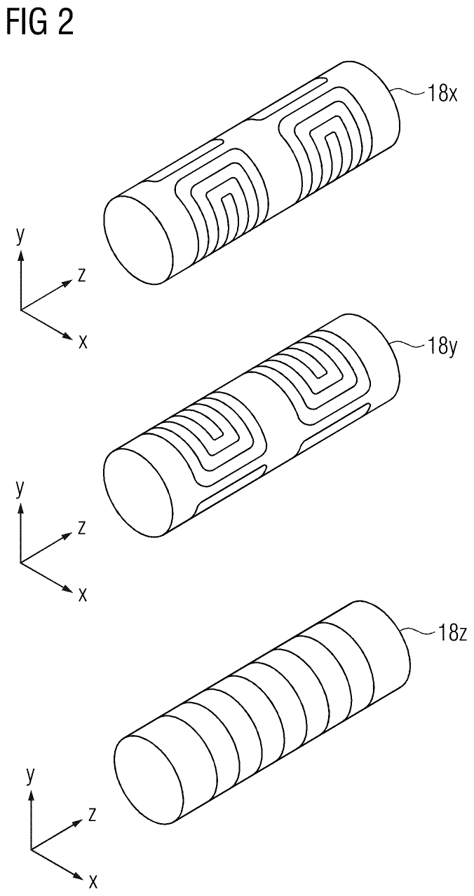

The magnetic unit 11 furthermore has a gradient coil unit 18 (with multiple gradient coils shown in FIG. 2) for generation of gradient magnetic fields, in particular of actual gradient magnetic fields, which overlap with the main magnetic field B₀ and are used for position encoding during imaging. The gradient coil unit 18 is controlled by a gradient control unit 19 of the magnetic resonance device 10. The magnetic unit 11 furthermore includes a radio-frequency antenna unit 20, which in the present exemplary embodiment is designed as a body coil permanently integrated into the magnetic resonance device 10. The radio-frequency antenna unit 20 is controlled by a radio-frequency antenna control unit 21 of the magnetic resonance device 10 and irradiates radio-frequency magnetic resonance sequences into an examination space, which is substantially formed by a patient receiving area 14 of the magnetic resonance device 10. As a result, an excitation of atomic nuclei occurs in the main magnetic field 13 generated by the main magnet 12. Magnetic resonance signals are generated by relaxation of the excited atomic nuclei. The radio-frequency antenna unit 20 is designed to receive the magnetic resonance signals.

For control of the main magnet 12 and of the gradient control unit 19 and for control of the radio-frequency antenna control unit 21, the magnetic resonance device 10 contains a system control unit 22. The system control unit 22 controls the magnetic resonance device 10 centrally, for example, the performance of a predetermined imaging gradient echo sequence. Furthermore, the system control unit 22 includes an evaluation unit (not shown in greater detail) for evaluation of the magnetic resonance signals that are captured during the magnetic resonance examination. Further, the magnetic resonance device 10 includes a user interface 23 which is connected to the system control unit 22. Control information such as for example imaging parameters, as well as reconstructed magnetic resonance images, may be displayed on a display unit 24, (for example, on at least one monitor), of the user interface 23 for medical personnel. Furthermore, the user interface 23 contains an input unit 25, by which information and/or parameters may be input by the medical personnel during a scanning procedure.

FIG. 2 shows three gradient coils 18x, 18y, 18z of the gradient coil unit 18. The gradient coil 18x, XGC, generates a gradient magnetic field, in particular an actual gradient magnetic field, with a gradient of the amount of the magnetic field in the X direction. The gradient coil 18y, YGC, generates a gradient magnetic field, in particular an actual gradient magnetic field, with a gradient of the amount of the magnetic field in the Y direction. The gradient coil 18z, ZGC, generates a gradient magnetic field, in particular an actual gradient magnetic field, with a gradient of the amount of the magnetic field in the Z direction. The vector fields B_{gx}(x,y,z), B_{gy}(x,y,z) B_{gz}(x,y,z) of the three gradient magnetic fields, in particular the associated setpoint gradient magnetic fields, may be oriented (only) in the Z direction; deviations from this ideal field direction may be estimated and/or taken into consideration using the proposed method.

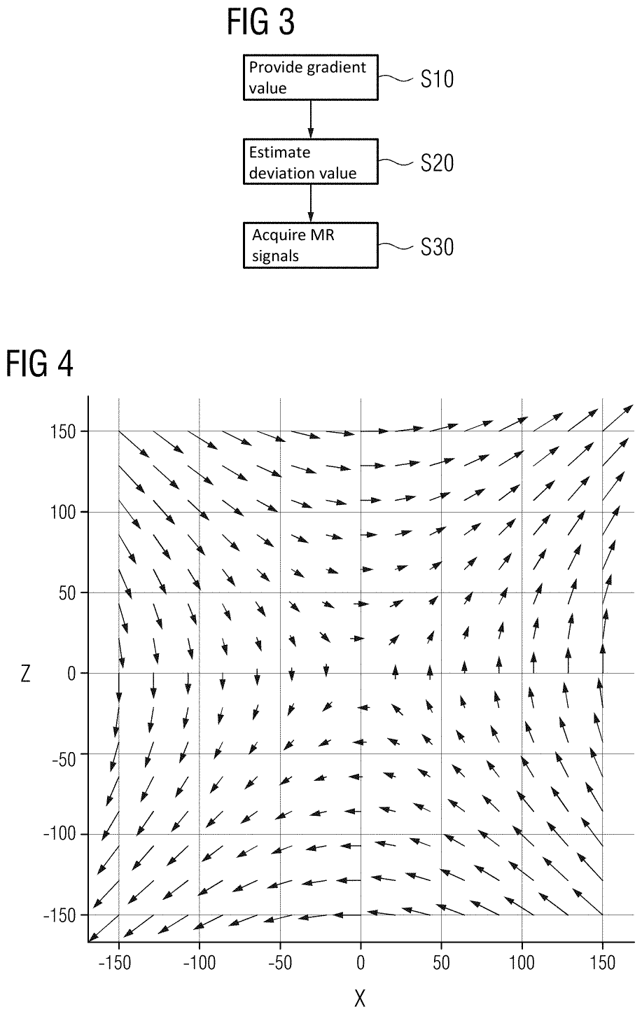

The magnetic resonance device 10, in particular the system control unit 22, is configured to perform a computer-implemented method, shown in FIG. 3, for estimating at least one value of a deviation, in particular of a Maxwell term. The at least one value of a deviation describes a deviation of an actual gradient magnetic field from a setpoint gradient magnetic field of the magnetic resonance device.

In act S10, at least one gradient value, for example, the gradient values GX, GY, GZ, is provided. Each of the gradient values GX, GY, GZ describes a gradient strength of the respective gradient magnetic field, in particular of the actual gradient magnetic field and/or of the associated setpoint gradient magnetic field.

In act S20, at least one value of a deviation is estimated, in that the gradient values GX, GY, GZ are applied to a magnetic field model. In accordance with the magnetic field model, the deviation of the actual gradient magnetic field from the setpoint gradient magnetic field is described by at least one vectorial component in a spatial direction X, Y deviating from the main magnetic field direction Z.

Optionally, in act S30, an acquisition and/or reconstruction of magnetic resonance signals takes place, having regard to the estimated at least one value of a deviation.

a. Various possible features and advantages of the method for estimating the at least one value of a deviation will be illustrated below. Using the method, in particular the following aspects may be improved compared to the prior art. First, not only may the amount or strength of the magnetic field, in particular of the at least one actual gradient magnetic field, be estimated, but also its direction. Second, for each Cartesian axis, deviations of the field may be estimated separately, depending on which gradient coil is active. Third, an estimation may be performed which does not presuppose that the main magnetic field B₀(x,y,z) is homogeneous (cf. assumption A4 of the Bernstein method). Fourth, no assumptions need be made about the field strength (cf. assumption A5 of the Bernstein method). As a result, estimations may also be made for low strengths of the main magnetic field (for example B₀≤0.5 T) and relatively high gradient strengths (for example Gₘₐₓ≥40 mT/m). The method may further be applied to high strengths of the main magnetic field with very high gradient strengths, for example B₀=3 T, Gₘₐₓ=300 mT/m.

An especially great potential advantage of the proposed method is that a Taylor series development is no longer necessary, so that no additional simplified assumptions need be made here, in that higher-order terms of the Taylor series are ignored. Further, one great potential advantage is that by selective application of the method as a function of the active gradient coils inadequacies of various conventional assumptions (cf. assumptions A1 . . . A5 of the Bernstein method) may consciously be taken into consideration.

### 7. Mathematical Principles

Let A(x,y,z) and B(x,y,z) be two vector fields. For rotation operator and divergence operator the associative law applies:

∇×(A+B)=∇×A+∇×B

∇×(A+B)=∇·A+∇·B

### 2. Physical Principles

Displacement currents and convection currents (genuine conduction currents) may be ignored within the FOV of the magnetic resonance device. Thus, it emerges from the Maxwell equations that the magnetic vector field B within the FOV is non-rotational and solenoidal:

$$\{ \begin{matrix}∇ \times B = {μ}_{0} J + \frac{1}{{c}^{2}} \frac{\partial E}{\partial t} = 0 \\ ∇ \cdot B = 0\end{matrix}$$

Thus the following relationships apply for the Cartesian components Bₓ, B_{y} and B_{z} of the vector field B:

$$∇ \times B = \vert \begin{matrix}i & j & k \\ \frac{\partial }{\partial x} & \frac{\partial }{\partial y} & \frac{\partial }{\partial z} \\ {B}_{x} & {B}_{y} & {B}_{z}\end{matrix} \vert = 0 \to \frac{\partial {B}_{x}}{\partial z} = \frac{\partial {B}_{z}}{\partial x} , \frac{\partial {B}_{y}}{\partial x} = \frac{\partial {B}_{x}}{\partial y} , \frac{\partial {B}_{z}}{\partial y} = \frac{\partial {B}_{y}}{\partial z}$$

$$∇ \cdot B = 0 \to \frac{\partial {B}_{x}}{\partial x} + \frac{\partial {B}_{y}}{\partial y} + \frac{\partial {B}_{z}}{\partial z} = 0$$

The total vector field B(x,y,z) in the imaging volume results from an overlap of the main magnetic field B₀(x,y,z) (generated by the main magnet 11) and the actual gradient magnetic fields B_{gx}(x,y,z), B_{gy}(x,y,z) and/or B_{gz}(x,y,z) (generated by the gradient coils 18x, 18y, 18z of the gradient coil unit 18). Because the sources of the overlapping magnetic fields, in other words of the main magnetic field and of the at least one actual gradient magnetic field, do not interact with one another and any transient effects caused by eddy currents may be ignored, the following results, for example, for an overlap of the main magnetic field B₀ and an actual gradient magnetic field B_{gx}(x,y,z) in the X direction:

$$\{ \begin{matrix}∇ \times ( {B}_{0} + {B}_{g x} ) = ∇ \times {B}_{0} + ∇ \times {B}_{g x} = 0 + 0 \\ ∇ \cdot ( {B}_{0} + {B}_{g x} ) = ∇ \cdot {B}_{0} + ∇ \cdot {B}_{g x} = 0 + 0\end{matrix}$$

From this, in the event that two or more gradient coils are active, these equations may be extended to all possible overlaps of magnetic fields; each individual contribution to the total magnetic field B(x,y,z) in the imaging volume (e.g. each actual gradient magnetic field B_{gx}(x,y,z), B_{gy}(x,y,z) and/or B_{gz}(x,y,z) and/or the main magnetic field B₀(x,y,z)) is thus non-rotational and solenoidal. This important finding enables each magnetic field contribution to be considered independently, as a result of which various technical advantages may be derived, as are shown below.

### 3. Estimation of Maxwell Terms with Active Gradient Coil 18x for Generation of a Magnetic Field Gradient in the X Direction

When using the expressions from section 2 for the Cartesian components of the actual gradient magnetic field B_{gx}(x,y,z) and the assumptions A1 to A3, the following results for the vectorial components B_{gx,x}, B_{gx,y} and B_{gx,z}:

$${B}_{gx , z} = x \cdot GX \to \{ \begin{matrix}\frac{\partial {B}_{gx , z}}{\partial x} = GX \\ \frac{\partial {B}_{gx , z}}{\partial y} = 0 \\ \frac{\partial {B}_{gx , z}}{\partial z} = 0\end{matrix} \} \to \begin{matrix}\{ \begin{matrix}\frac{\partial {B}_{gx , x}}{\partial x} = \frac{\partial {B}_{gx , y}}{\partial y} = 0 \\ \frac{\partial {B}_{gx , x}}{\partial y} = \frac{\partial {B}_{gx , y}}{\partial x} = 0 \\ \frac{\partial {B}_{gx , x}}{\partial z} = \frac{\partial {B}_{gx , z}}{\partial x} = GX\end{matrix} \} \to {B}_{gx , x} = z \cdot GX \\ \{ \begin{matrix}\frac{\partial {B}_{gx , y}}{\partial x} = \frac{\partial {B}_{gx , x}}{\partial y} = 0 \\ \frac{\partial {B}_{gx , y}}{\partial y} = \frac{\partial {B}_{gx , x}}{\partial x} = 0 \\ \frac{\partial {B}_{gx , y}}{\partial z} = \frac{\partial {B}_{gx , z}}{\partial y} = 0\end{matrix} \} \to {B}_{gx , y} = 0\end{matrix}$$

The deviation of the actual gradient magnetic field from the setpoint gradient magnetic field is described here by the vectorial components B_{gx,x} and B_{gx,y} of the spatial directions (X and Y direction) deviating from the main magnetic field direction (Z direction). A gradient coil 18x for generation of a magnetic field oriented in the Z direction with a linear magnetic field gradient in the X direction thus generates an equally large, concomitant orthogonal magnetic field, which is oriented in the X direction and changes linearly with the z coordinate. The vectorial component B_{gx,x} has a linear dependency on the z coordinate. In contrast, the concomitant orthogonal magnetic field oriented in the Y direction is negligibly small or approximately 0.

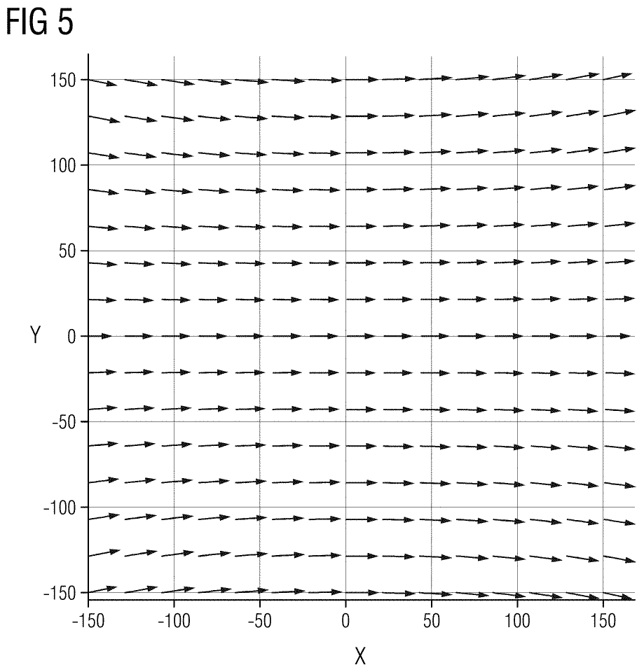

FIGS. 4 and 5 show by way of example a magnetic field B(x,y,z) in each case as a vector field, these confirming the validity of the above theoretical results. In FIG. 4, y=0 and in FIG. 5, z=z₀>0. Whereas, in FIG. 4, the X component of the vectors changes significantly depending on the z coordinate. In FIG. 5, the Y component of the vectors is also negligible where z=z₀>0.

### 4. Estimation of Maxwell Terms with Active Gradient Coil 18y for Generation of a Magnetic Field Gradient in the Y Direction

When using the expressions from section 2 for the Cartesian components of the actual gradient magnetic field B_{gy}(x,y,z) and the assumptions A1 to A3, the following results for the vectorial components B_{gy,x}, B_{gy,y} and B_{gy,z}:

$${B}_{gy , z} = y \cdot GY \to \{ \begin{matrix}\frac{\partial {B}_{gy , z}}{\partial x} = 0 \\ \frac{\partial {B}_{gy , z}}{\partial y} = GY \\ \frac{\partial {B}_{gy , z}}{\partial z} = 0\end{matrix} \} \to \begin{matrix}\{ \begin{matrix}\frac{\partial {B}_{gy , x}}{\partial x} = \frac{\partial {B}_{gy , y}}{\partial y} = 0 \\ \frac{\partial {B}_{gy , x}}{\partial y} = \frac{\partial {B}_{gy , y}}{\partial x} = 0 \\ \frac{\partial {B}_{gy , x}}{\partial z} = \frac{\partial {B}_{gy , z}}{\partial x} = 0\end{matrix} \} \to {B}_{gy , x} = 0 \\ \{ \begin{matrix}\frac{\partial {B}_{gy , y}}{\partial x} = \frac{\partial {B}_{gy , x}}{\partial y} = 0 \\ \frac{\partial {B}_{gy , y}}{\partial y} = \frac{\partial {B}_{gy , x}}{\partial x} = 0 \\ \frac{\partial {B}_{gy , y}}{\partial z} = \frac{\partial {B}_{gy , z}}{\partial y} = GY\end{matrix} \} \to {B}_{gy , y} = z \cdot GY\end{matrix}$$

The deviation of the actual gradient magnetic field from the setpoint gradient magnetic field is described here by the vectorial components B_{gy,x} and B_{gy,y} of the spatial directions (X and Y direction) deviating from the main magnetic field direction (Z direction). A gradient coil 18y for generation of a magnetic field oriented in the Z direction with a linear magnetic field gradient in the Y direction thus generates an equally large, concomitant orthogonal magnetic field, which is oriented in the Y direction and changes linearly with the z coordinate. The vectorial component B_{gy,y} has a linear dependency on the z coordinate. In contrast, the concomitant orthogonal magnetic field oriented in the X direction is negligibly small or approximately 0.

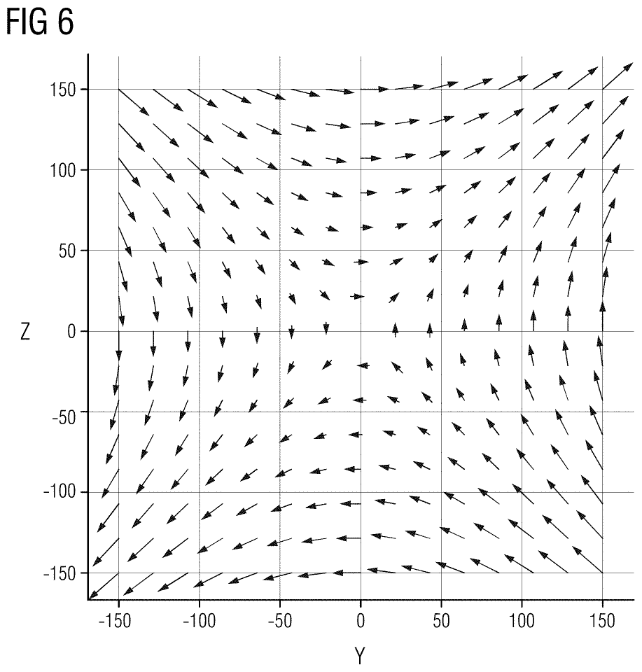

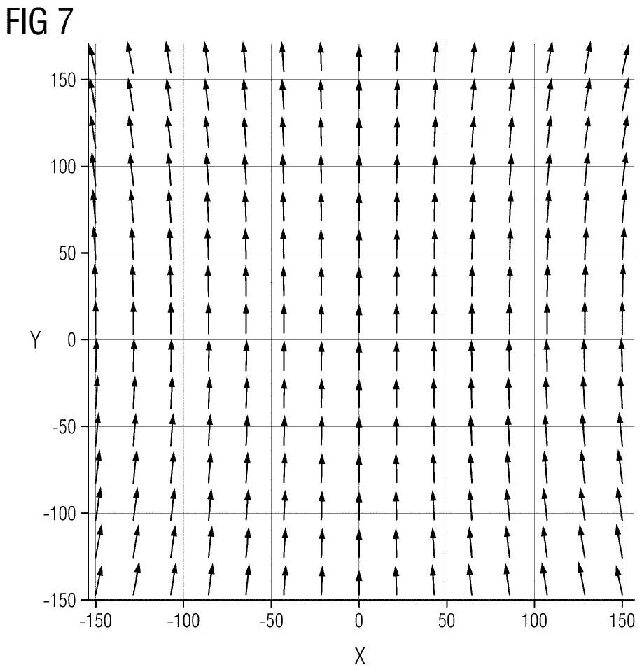

FIGS. 6 and 7 show by way of example a magnetic field B(x,y,z) in each case as a vector field, these confirming the validity of the above theoretical results. In FIG. 6, x=0 and in FIG. 7, z=z₀>0. Whereas, in FIG. 6, the Y component of the vectors changes significantly depending on the z coordinate. In FIG. 7, the X component of the vectors is also negligible where z=z₀>0.

### 5. Estimation of Maxwell Terms with Active Gradient Coil 18z for Generation of a Magnetic Field Gradient in the Z Direction

When using the expressions from section 2 for the Cartesian components of the actual gradient magnetic field B_{gz}(x,y,z) and the assumptions A1 to A3, the following results for the vectorial components B_{gz,x}, B_{gz,y} and B_{gz,z}:

$${B}_{gz , z} = z \cdot GZ \to \{ \begin{matrix}\frac{\partial {B}_{gz , z}}{\partial x} = 0 \\ \frac{\partial {B}_{gz , z}}{\partial y} = 0 \\ \frac{\partial {B}_{gz , z}}{\partial z} = GZ\end{matrix} \} \to \begin{matrix}\{ \begin{matrix}\frac{\partial {B}_{gz , x}}{\partial x} = \frac{\partial {B}_{gz , y}}{\partial y} = \frac{GZ}{2} \\ \frac{\partial {B}_{gz , x}}{\partial y} = \frac{\partial {B}_{gz , y}}{\partial x} = 0 \\ \frac{\partial {B}_{gz , x}}{\partial z} = \frac{\partial {B}_{gz , z}}{\partial x} = 0\end{matrix} \} \to {B}_{gz , x} = - x \frac{GZ}{2} \\ \{ \begin{matrix}\frac{\partial {B}_{gz , y}}{\partial x} = \frac{\partial {B}_{gz , x}}{\partial y} = 0 \\ \frac{\partial {B}_{gz , y}}{\partial y} = \frac{\partial {B}_{gz , x}}{\partial x} = \frac{GZ}{0} \\ \frac{\partial {B}_{gz , y}}{\partial z} = \frac{\partial {B}_{gz , z}}{\partial y} = 0\end{matrix} \} \to {B}_{gz , y} = - y \frac{GZ}{2}\end{matrix}$$

The deviation of the actual gradient magnetic field from the setpoint gradient magnetic field is described here by the vectorial components B_{gz,x} and B_{gz,y} of the spatial directions (X and Y direction) deviating from the main magnetic field direction (Z direction). A gradient coil 18z for generation of a magnetic field oriented in the z direction with a linear magnetic field gradient in the Z direction thus generates two half as large, concomitant orthogonal magnetic fields: one is oriented opposite to the X direction and changes linearly with the x coordinate; the other is oriented opposite to the Y direction and changes linearly with the y coordinate. The vectorial component B_{gz,x} has a linear dependency on the x coordinate; the vectorial component B_{gz,y} has a linear dependency on the y coordinate.

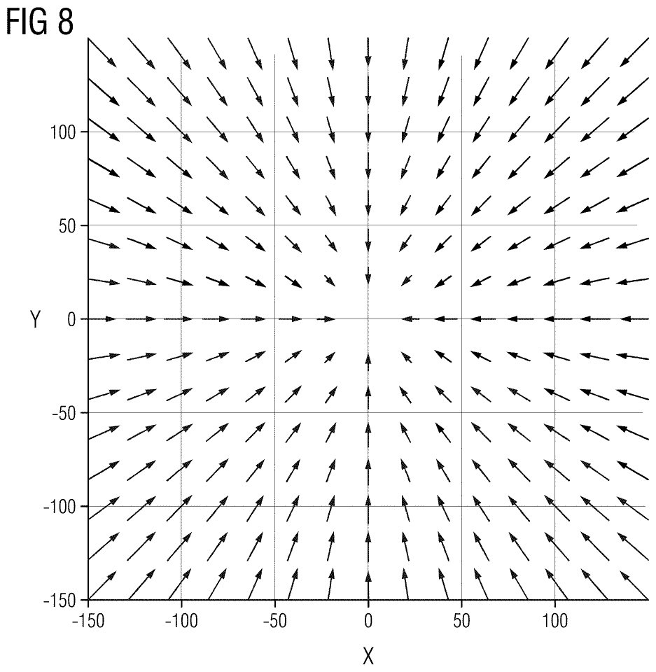

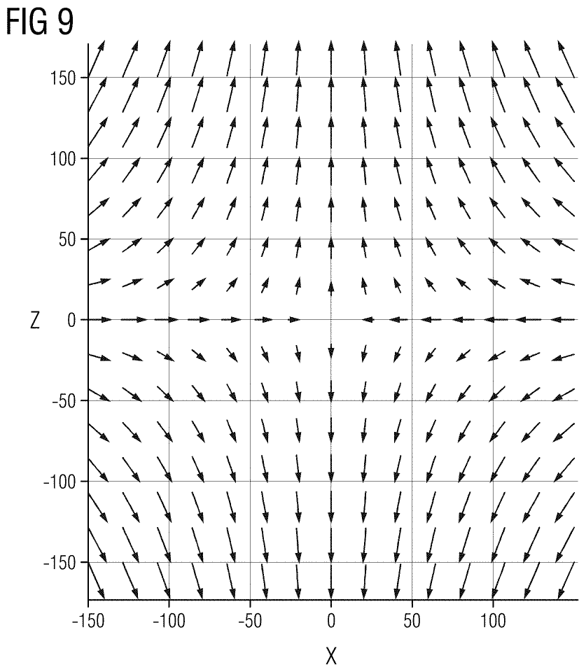

FIGS. 8-10 show by way of example a magnetic field B(x,y,z) in each case as a vector field, these confirming the validity of the above theoretical results. In FIG. 8, z=0, in FIG. 9, y=0, and in FIG. 10, x=0.

### 6. Overview of the Estimations of the Maxwell Terms

In accordance with the explanations in sections 1-6, a magnetic field model has been developed, in accordance with which the deviation of the actual gradient magnetic field from the setpoint gradient magnetic field is described by at least one vectorial component in a spatial direction deviating from the main magnetic field direction.

Depending on which of the gradient coils 18x, 18y, 18z is active, the (resultant) gradient magnetic field includes a first actual gradient magnetic field with a magnetic field gradient in the X direction, a second actual gradient magnetic field with a magnetic field gradient in the Y direction and/or a third actual gradient magnetic field with a magnetic field gradient in the Z direction. X direction, Y direction and Z direction are in this case orthogonal to one another.

The vector field of the main magnetic field is oriented in the main magnetic field direction, the Z direction. The vector field of the first actual gradient magnetic field contains the vectors B_{gx}(x,y,z) with the vector components B_{gx,x}, B_{gx,y} and B_{gx,z}. The vector field of the second actual gradient magnetic field contains the vectors B_{gy}(x,y,z) with the vector components B_{gy,x}, B_{gy,y} and B_{gy,z}. The vector field of the third actual gradient magnetic field contains the vectors B_{gz}(x,y,z) with the vector components B_{gz,x}, B_{gz,y} and B_{gz,z}. The vector components B_{gx,x}, B_{gx,y}, B_{gy,x}, B_{gy,y}, B_{gz,x} and B_{gz,y} may be viewed as values of a deviation, in particular concomitant field components, which describe a deviation of the actual gradient magnetic field from a setpoint gradient magnetic field of the magnetic resonance device 10. The setpoint gradient magnetic field may provide that the vector components B_{gx,x}, B_{gx,y}, B_{gy,x}, B_{gy,y}, B_{gz,x} and B_{gz,y} are equal to zero. In accordance with sections 4 and 5 this is in particular not the case for B_{gx,x}, B_{gy,y}, B_{gz,x} and B_{gz,y}.

### 7. Calculation of Field Errors Caused by Maxwell Terms in the Case of a Homogeneous Main Magnetic Field

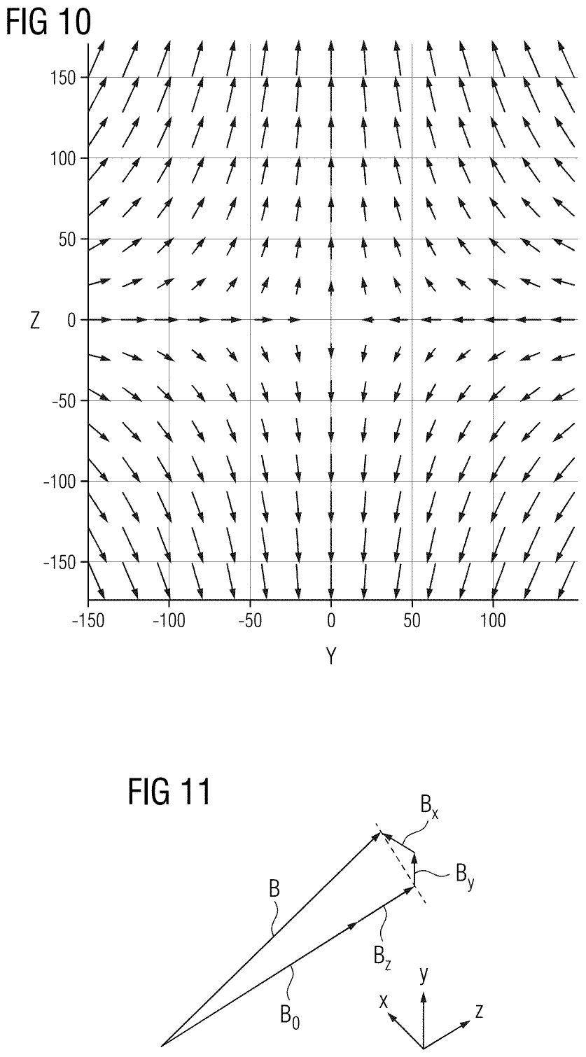

FIG. 11 shows by way of example an overlap of various magnetic fields, in that vector components are combined, in particular added, to form a resultant magnetic field. In this case B₀ is the vector of the main magnetic field that is generated by the main magnet 12. B_{z} is the desired (setpoint) component of the gradient magnetic field along the Z axis. Bₓ and B_{y} are concomitant field components along the X and Y axis. If multiple gradient coils are active simultaneously, these concomitant field components may result from a sum of multiple concomitant field components, e.g. Bₓ=B_{gx,x}+B_{gy,x}+B_{gz,x} and B_{y}=B_{gx,y}+B_{gy,y}+B_{gz,y}.

In particular, if the main magnet 12 is properly shimmed, the main magnetic field B₀ may have a very high homogeneity within the FOV of just a few ppm deviation from a target value. In this case the vector B₀ of the main magnetic field has a constant amount B₀ and is parallel to the Z axis, i.e., B₀=B₀·k, wherein k is the unit vector in the Z direction. By using the estimation in accordance with sections 3-5 the following results for vector field B(x,y,z) of the total magnetic field:

$$B ( x , y , z ) = {B}_{x} i + {B}_{y} j + ( {B}_{0} + {B}_{z} ) k == ( z \cdot GX - x \frac{G Z}{2} ) i + ( z \cdot Gy - y \frac{G Z}{2} ) j + ( {B}_{0} + x \cdot GX + y \cdot GY + z \cdot GZ ) k$$

In this case, i and j are the unit vectors in the X and Y direction. Thus, following a provision of a parameter which describes the main magnetic field, such as for instance the vector field B₀, the total magnetic field B(x,y,z) may be estimated using the vector field B₀, the gradient values GX, GY, GZ and the concomitant field components.

The last equation may of course be simplified if only one or two gradient coils are active. For example, if only the gradient coil 18x for generation of a magnetic field gradient in the X direction is active, GY=GZ=0, and the resultant spatial distribution of the vectorial magnetic field may be estimated with the following equation:

B(x,y,z)=(z·GX)i+(B₀+x·GX)k

It is further conceivable, using the estimated vector field B(x,y,z), to correct encoding errors, induced by Maxwell terms, of magnetic resonance signals. For example, during a readout phase the local frequency is proportionally dependent on the amount of B(x,y,z)—and not for instance as when viewed in a conventionally idealized manner proportionally dependent on BZ(x,y,z)=B₀+x·GX. The actual spatial distribution of the frequency encoding for the local magnetic resonance signal in this case produces:

ω(x,y,z)=γ·|B(x,y,z)|=γ·\sqrt{(z·GX)²+(B₀+x·GX)²}

In this case, ω(x,y,z) the local Larmor frequency and γ the gyromagnetic ratio of the nucleus are of interest, mostly of the water protons. This expression may also be used directly to correct the geometric distortions in the magnetic resonance images. The advantage of the new method compared to the prior art is in particular that no development into Taylor series and/or assumptions about the relative strength of the gradient fields (cf. assumption A5 of the Maxwell method) are necessary. Thus the method also works for magnetic resonance examinations with a low or very low field.

Using the estimated values of a deviation, in particular the concomitant field components, a correction of magnetic resonance signals, in particular of an encoding of magnetic resonance signals, may be performed. In particular, the correction may include a calculation of a Larmor frequency in dependency on the values of a deviation.

### 8. Calculation of Field Errors Caused by Maxwell Terms in the Case of an Inhomogeneous Main Magnetic Field

In particular, to be able to produce cost-effective magnetic resonance devices, in particular main magnets, compromises may be required as regards the achievable homogeneity of the static main magnetic field B₀. The proposed method enables the effects of such inhomogeneities to be calibrated and/or corrected, in order to minimize any image artifacts connected thereto.

Various methods are known in the prior art for creating field maps of an inhomogeneous static magnetic field, such as the main magnetic field B₀(x,y,z), e.g., using a 3D magnetic field camera. It is possible to use such field maps to correct signal encoding errors when concomitant fields exist.

The total magnetic field B(x,y,z) may result from an overlap of all contributing field sources. If all gradient coils are active, then in accordance with the explanations in sections 2-4 the actual field distribution may be expressed by:

$$B ( x , y , z ) = [ ijk ] \cdot [ \begin{matrix}{B}_{0 x} ( x , y , z ) + z \cdot GX - x \frac{GZ}{2} \\ {B}_{0 y} ( x , y , z ) + z \cdot GY - y \frac{GZ}{2} \\ {B}_{0 z} ( x , y , z ) + x \cdot GX + y \cdot GY + z \cdot GZ\end{matrix} ]$$

In this case, B₀ₓ(x,y,z), B_{0y}(x,y,z), B_{0z}(x,y,z) are the vector components of the vector field B₀(x,y,z) of the main magnetic field.

In certain situations, this expression may be simplified. If, for example, the main magnetic field is in fact inhomogeous, but is nevertheless reasonably parallel to the Z axis and only the X gradient coil 18x is active, then:

$$B ( x , y , z ) = [ ijk ] \cdot [ \begin{matrix}z \cdot GX \\ 0 \\ {B}_{0 z} ( x , y , z ) + x \cdot GX\end{matrix} ]$$

Accordingly, the following applies for the spatial distribution of the frequency encoding of local magnetic resonance signals:

ω(x,y,z)=γ·|B(x,y,z)|=γ·\sqrt{(z·GX)²+[B_{0z}(x,y,z)+x·GX]²}

The proposed method may advantageously also be used to take into consideration larger inhomogeneities of the main magnetic field, e.g., in the periphery of the FOV.

### 9. Model-Based Image Reconstruction

An image reconstruction may advantageously, in accordance with the proposed magnetic field model, take into consideration the phase errors that are induced by the concomitant fields. With this model, an instantaneous frequency of the magnetic resonance signals at a given spatial location may be modeled:

$$ω ( x , y , z , t ) = γ \cdot \vert B ( x , y , z , t ) \vert == γ \cdot \vert [ ijk ] \cdot [ \begin{matrix}{B}_{0 x} ( x , y , z , t ) + z \cdot GX ( t ) - x \frac{GZ ( t )}{2} \\ {B}_{0 y} ( x , y , z , t ) + z \cdot GY ( t ) - y \frac{GZ ( t )}{2} \\ {B}_{0 z} ( x , y , z , t ) + x \cdot GX ( t ) + y \cdot GY ( t ) + z \cdot GZ ( t )\end{matrix} ] \vert$$

In this case, B(x,y,z,t) advantageously takes into consideration a temporal drift of the magnetic field, in particular of the main magnetic field, for example, because of floor vibrations or as a result of thermal heating of various components of the magnetic unit 11 (e.g. field coils, shim irons, formers or permanent magnets). This drift may be calibrated in advance, e.g., using a 3D magnetic field camera, and recalibrated during a magnetic resonance scan, e.g., using one or more sensors, in particular temperature sensors and/or vibration sensors, which in particular capture (actual) ambient parameters in real time. The expressions GX(t), GY(t), and GZ(t), in particular, describe gradient waveforms or gradient pulses which are applied and/or used during the magnetic resonance scan.

In conclusion, it is once again noted that the methods described in detail above and the magnetic resonance device relate solely to exemplary embodiments that may be modified by the person skilled in the art in a variety of ways, without departing from the scope of the disclosure. Further, the use of the indefinite article “a” or “an” does not preclude that the features in question may also be present multiple times. Likewise, the term “unit” does not rule out that the components in question include multiple interacting subcomponents that if appropriate may also be distributed spatially.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for estimating at least one value of a deviation, wherein each value of the at least one value of the deviation describes a deviation of a respective actual gradient magnetic field from a respective setpoint gradient magnetic field of a magnetic resonance device, the method comprising:
providing at least one gradient value, wherein each gradient value of the at least one gradient value describes a gradient strength of the respective setpoint gradient magnetic field;
generating, by the magnetic resonance device, a main magnetic field in a main magnetic field direction; and
estimating the at least one value of the deviation by applying the at least one gradient value to a magnetic field model,
wherein, in accordance with the magnetic field model, the deviation of the respective actual gradient magnetic field from the respective setpoint gradient magnetic field is described by at least one vectorial component in a spatial direction deviating from the main magnetic field direction.

2. The method of claim 1, wherein the at least one value of the deviation comprises a Maxwell term.

3. The method of claim 1, wherein the at least one vectorial component has a linear dependency on at least one coordinate of the spatial direction.

4. The method of claim 1, wherein a vector field of the main magnetic field is oriented in the main magnetic field direction,
wherein an actual vector field of the respective actual gradient magnetic field contains at least one vector comprising at least one vector component that deviates from the main magnetic field direction, and
wherein the at least one value of the deviation describes the deviation of the at least one vector component from the main magnetic field direction.

5. The method of claim 1, wherein the respective actual gradient magnetic field comprises: a first actual gradient magnetic field with a magnetic field gradient in a first spatial direction; a second actual gradient magnetic field with a magnetic field gradient in a second spatial direction; and/or a third actual gradient magnetic field with a magnetic field gradient in a third spatial direction, and
wherein the first spatial direction, the second spatial direction, and the third spatial direction are orthogonal to one another.

6. The method of claim 5, wherein the first spatial direction is an X direction, the second spatial direction is a Y direction, and the third spatial direction is a Z direction,
wherein the Z direction is the main magnetic field direction,
wherein, in accordance with the magnetic field model, Bₓₓ=z·GX, B_{xy}=0 applies for the at least one value of the deviation for the first actual gradient magnetic field, B_{yx}=0, B_{yy}=z·GY applies for the at least one value of the deviation for the second actual gradient magnetic field, and/or
$${B}_{z x} = - x \frac{G Z}{2} , {B}_{z y} = - y \frac{G Z}{2}$$
applies for the at least one value of the deviation for the third actual gradient magnetic field, and wherein:
GX is the gradient strength in the X direction,
GY is the gradient strength in the Y direction,
GZ is the gradient strength in the Z direction,
x is a coordinate in the X direction,
y is a coordinate in the Y direction, and
z is a coordinate in the Z direction.

7. The method of claim 6, further comprising:
correcting magnetic resonance signals using the at least one value of the deviation.

8. The method of claim 7, wherein the correcting of the magnetic resonance signals comprises correcting an encoding of the magnetic resonance signals.

9. The method of claim 7, wherein the correcting comprises calculating a Larmor frequency in dependency on the at least one value of the deviation.

10. The method of claim 1, further comprising:
correcting magnetic resonance signals using the at least one value of the deviation.

11. The method of claim 10, wherein the correcting of the magnetic resonance signals comprises correcting an encoding of the magnetic resonance signals.

12. The method of claim 10, wherein the correcting comprises calculating a Larmor frequency in dependency on the at least one value of the deviation.

13. The method of claim 1, further comprising:
reconstructing at least one magnetic resonance image using the at least one value of the deviation,
wherein, during the reconstructing of the at least one magnetic resonance image, phase errors caused by the deviation of the respective actual gradient magnetic field are corrected using the at least one value of the deviation.

14. The method of claim 1, further comprising:
providing at least one parameter which describes the main magnetic field; and
estimating a total magnetic field using the at least one parameter, the at least one gradient value, and the at least one value of the deviation.

15. The method of claim 14, further comprising:
performing a magnetic resonance scan,
wherein, prior to the performing of the magnetic resonance scan, the at least one parameter of the main magnetic field has been calibrated,
wherein, during the performing of the magnetic resonance scan, the calibrated at least one parameter is recalibrated, and
wherein the estimating of the total magnetic field takes place using the recalibrated at least one parameter.

16. The method of claim 15, wherein the recalibration is conducted in real time during the performing of the magnetic resonance scan.

17. A system control unit of a magnetic resonance device, the system control unit comprising:
at least one processor; and
at least one memory, wherein the at least one memory and the at least one processor are configured to:
receive at least one gradient value, wherein each gradient value of the at least one gradient value describes a gradient strength of a respective setpoint gradient magnetic field;
generate a main magnetic field in a main magnetic field direction; and
estimate at least one value of a deviation of an actual gradient magnetic field from the respective setpoint gradient magnetic field of the magnetic resonance device by applying the at least one gradient value to a magnetic field model,
wherein, in accordance with the magnetic field model, the deviation of the respective actual gradient magnetic field from the respective setpoint gradient magnetic field is described by at least one vectorial component in a spatial direction deviating from the main magnetic field direction.

18. A magnetic resonance device comprising:
a system control unit configured to:
receive at least one gradient value, wherein each gradient value of the at least one gradient value describes a gradient strength of a respective setpoint gradient magnetic field;
generate a main magnetic field in a main magnetic field direction; and
estimate at least one value of a deviation of an actual gradient magnetic field from the respective setpoint gradient magnetic field of the magnetic resonance device by applying the at least one gradient value to a magnetic field model,
wherein, in accordance with the magnetic field model, the deviation of the actual gradient magnetic field from the respective setpoint gradient magnetic field is described by at least one vectorial component in a spatial direction deviating from the main magnetic field direction.
